(19) United States
(12) Patent Application Publication
(10) Pub. No.: US 2004/0010746 A1
(43) Pub. Date: Jan. 15, 2004

(54) Forward error correction system for wireless communications

(76) Inventors: L. Victor Lucas, Seattle, WA (US); Carl F. Andren, Indialantic, FL (US); Perry W. Frogge, Palm Bay, FL (US)

Correspondence Address: GARY R. STANFORD, 610 WEST LYNN, AUSTIN, TX, 78703, US

(21) Appl. No.: 10/192,037

(22) Filed: Jul. 10, 2002

(51) Int. Cl. H03M 13/00

(52) U.S. Cl. 714/781

(57) ABSTRACT

An FEC scheme for wireless receivers including a symbol detector, a symbol selector, CRC logic and output logic. The detector correlates each digital group of the packet with a symbol family and provides possible symbols and corresponding correlation factors. The selector selects several possible symbols for each digital group having the highest correlation factors. The CRC logic calculates possible CRC values for the packet using combinations of the selected symbols. The output logic evaluates the possible CRC values to determine whether there is a correct symbol combination. The system may include logic that determines a symbol quality (SQ) metric for each digital group based on a difference between the two highest correlation factors. The system may include a rank value filter that selects a predetermined number of second choice symbols based on the SQ metrics. The CRC logic calculates the CRC values using combinations of first and second choice symbols.

### FIELD OF THE INVENTION

The present invention relates to wireless communications, and more particularly to a forward error correction system for a wireless transceiver implemented to use cyclical redundancy code (CRC) error detection technique.

### DESCRIPTION OF RELATED ART

The Electrical and Electronics Engineers, Inc. (IEEE) 802.11 standard originally defined an arbitrary interface between the baseband processor (BBP) and the medium access control (MAC) device. The original BBP/MAC interface was defined based on wired configurations and is not optimal for wireless configurations. In particular, the original standard assumed a relatively low packet error rate (PER) that was valid for wired configurations but that was not valid for wireless configurations. The standard relies upon a simple a simple cyclical redundancy code (CRC) error detection technique in which a CRC is generated and appended to each packet prior to transmission. A 16-bit header CRC is also calculated in similar manner and stored within the header of the packet. The particular calculation for CRC, defined in the 802.11 specification, involves a well-known mathematical function involving polynomial division that is not described herein. According to the IEEE 802.11 standard, the receiver performs a similar function incorporating the CRC to obtain a CRC remainder, which is supposed to equal a predetermined value, such as, for example, 0xC704DD7B (where the prefix “0x” demotes hexadecimal notation). Alternative CRC schemes are contemplated, such as a predetermined value of zero, or such as comparison of the calculated CRC on all but the CRC portion with the transmitted CRC stripped from the transmitted packet.

The CRC error detection technique was sufficient for wired embodiments in which very low PERs were expected. The CRC error detection technique was not adequate, however, for wireless configurations which are characterized by a relatively high PER since a significant number of packets are simply rejected without further processing. The HFA3863 Direct Sequence Spread Spectrum (DSSS) baseband processor by Intersil, for example, produces a significant number of received packets with a small number of symbol errors. The standard CRC technique caused a significant number of packet rejections which limited wireless performance. It is desired to salvage as many of these erroneous packets as possible to improve performance. Although error detection and correction schemes are known, the existing baseline IEEE 802.11 standard does not contemplate their use. The IEEE 802.11 standard also tends to limit variations in the BBP/MAC interface.

### SUMMARY OF THE INVENTION

A forward error correction system for a wireless receiver according to an embodiment of the present invention includes a symbol detector, a symbol selector, CRC logic and output logic. The symbol detector correlates each received digital group of a packet with a selected symbol family and provides a set of possible symbols and corresponding correlation factors. The symbol selector selects several possible symbols for each digital group that have the highest correlation factors. The CRC logic calculates several possible CRC values for the packet using combinations of the selected possible symbols. The output logic evaluates the possible CRC values to determine whether there is a correct symbol combination for the packet.

The forward error correction system may include symbol quality logic that determines a symbol quality metric for each digital group based on a difference between a highest correlation factor and a second highest correlation factor. The forward error correction system may further include a rank value filter that selects a predetermined number of second choice symbols based on the symbol quality metrics. The CRC logic may calculate each of the possible CRC values using combinations of the second choice symbols and corresponding first choice symbols.

A method of forward error correction for a wireless receiver includes correlating digital groups of a packet with a symbol family and providing possible symbols and corresponding correlation factors, selecting a plurality of the possible symbols for each digital group that have higher correlation factors compared to other possible symbols, determining a plurality of possible CRC values for the packet using combinations of the plurality of possible symbols for each digital group, and determining if any of the plurality of possible CRC values indicates a valid packet.

The method may include selecting a first choice symbol having a highest correlation factor and a second choice symbol having a second highest correlation factor. The method may include determining a symbol quality factor for each digital group based on a difference between the highest and second highest correlation factors. The method may include selecting a predetermined number of second choice symbols based on symbol quality factors and calculating each possible CRC value using a different combination of the selected second choice symbols and corresponding first choice symbols. The selection of second choice symbols may include selecting those symbols associated with the lowest symbol quality metrics of the packet.

### BRIEF DESCRIPTION OF THE DRAWINGS

A better understanding of the present invention can be obtained when the following detailed description of exemplary embodiments is considered in conjunction with the following drawings, in which:

FIG. 1 is a block diagram of a wireless radio frequency (RF) transceiver implemented according to an embodiment of the present invention.

FIG. 2 is a more detailed block diagram illustrating a portion of an exemplary configuration of the RX processor of FIG. 1 interfaced to a portion of the MAC interface that includes a MAC buffer.

FIG. 3 is a more detailed block diagram of an exemplary embodiment of the rank value filter of FIG. 2.

FIG. 4 is a flowchart diagram illustrating operation of the rank value filter of FIG. 2 in accordance with an exemplary simplified procedure for determining and storing the second choice symbols having the lowest symbol quality metrics.

FIG. 5 is a more detailed block diagram of an exemplary configuration of the CRC logic of FIG. 2.

FIGS. 6, 7 and 8 are tabular diagrams illustrating replacement of symbol values to update the possible CRC values as controlled by the address control logic of FIG. 5.

FIG. 9 is a more detailed block diagram of the control and output logic of FIG. 2.

### DETAILED DESCRIPTION OF EMBODIMENT(S) OF THE INVENTION

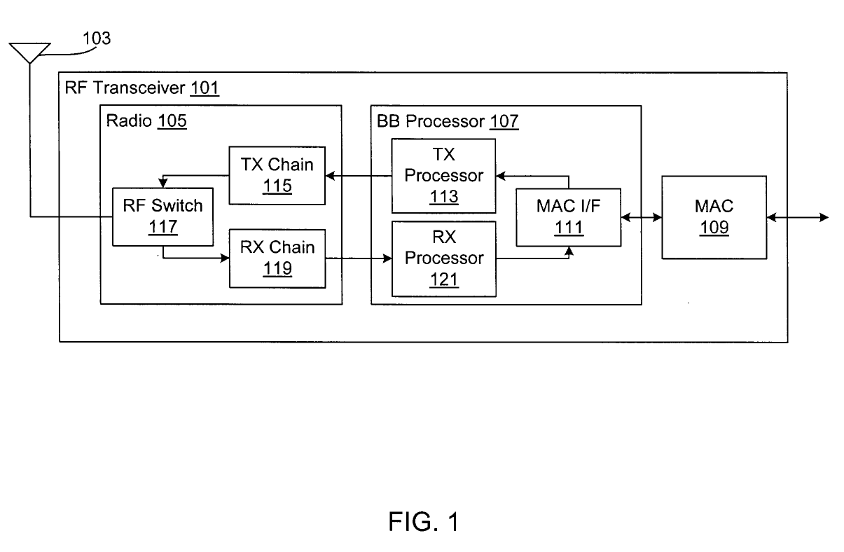

FIG. 1 is a block diagram of a wireless radio frequency (RF) transceiver 101 implemented according to an embodiment of the present invention. The transceiver 101 may be used to communicate with one or more similar wireless devices across a wireless medium, such as within a wireless local area network (WLAN) or the like. The transceiver 101 may be used by any type of device to incorporate wireless communication capabilities, such as a wireless access point (AP), any type of computer or computer system (e.g., personal computers, laptop computers, desktop computers, etc.,), printing devices including any type of printer technology, personal digital assistants (PDAs) or the like, scanners, fax machines, etc.

The transceiver 101 may be configured as a plug-in peripheral or expansion card that plugs into an appropriate slot or interface of a computer system, such as a Personal Computer Memory Card International Association (PCMCIA) card or PC Card or may be implemented according to any type of expansion or peripheral standard, such as according to the peripheral component interconnect (PCI), the Industry Standard Architecture (ISA), the Extended-ISA (EISA) standard, etc. Mini PCI cards with antennas embedded in displays are also contemplated. Self-contained or standalone packaging with appropriate communication interface(s) is also contemplated, which is particularly advantageous for APs. The transceiver 101 may be implemented as a separate unit with serial or parallel connections, such as a Universal Serial Bus (USB) connection or an Ethernet interface (twisted-pair, coaxial cable, etc.), or any other suitable interface to the device. Other types of wireless devices are contemplated, such as any type of wireless telephony device including cellular phones.

The transceiver 101 communicates via the wireless medium using one or more antennas 103 coupled to an internal radio chip or device (radio) 105. The radio 105 generally converts between RF signals and Baseband signals and is coupled to a Baseband (BB) processor 107. Within the radio 105, an RF switch 117 selects either a transmission (TX) chain 115 for transmission or an RF chain 119 for reception of packets. The Baseband processor 107 is further coupled to a medium access control (MAC) device 109 that communicates with the associated communication device or system. Digital data sent from or received by the transceiver 101 is processed through the MAC 109. For transmission, the MAC 109 asserts digital data signals via a MAC interface (I/F) 111 to a TX processor 113, which formulates data into packets for transmission. The digital packet information is converted to analog signals using a digital to analog converter (DAC) (not shown) and processed by the TX chain 115 for converting the packets into RF signals suitable for transmission via the antenna 103. Although not explicitly shown, the TX chain 115 typically includes upconverters or mixers to convert a baseband analog signal into an intermediate frequency (IF) signal and to convert the IF signal to RF for transmission.

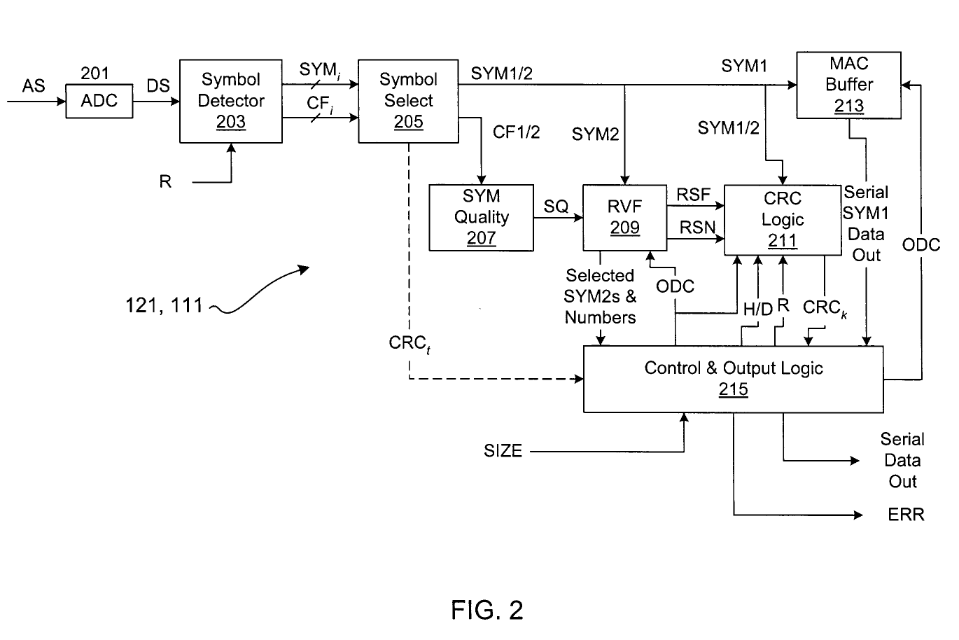

For receive operations, the RX chain 119 extracts Baseband signals from a received RF signal and provides digital Baseband signals to a receive (RX) processor 121 via an analog to digital converter (ADC) 201 (FIG. 2). Although not explicitly shown, the RX chain 119 typically includes downconverters or mixers to convert from RF to IF and from IF to a baseband analog signal. Alternative zero intermediate interface (ZIF) or direct conversion architectures without the IF portions are also contemplated. The baseband analog signal is converted to digital format using the ADC 201. The RX processor 121 generally performs the inverse functions of the TX processor 113 to extract data from received packets into data signals for the associated communication device. The data is forwarded to the MAC 109 via the MAC I/F 111 as shown. Other functions are not shown, such as automatic gain control (AGC) functions or the like for amplifying or attenuating the received signal to a desired target power level. The transceiver 101 may be implemented according to the IEEE 802.11b standard operating at approximately 2.4 Gigahertz (GHz) for use with a WLAN. It is appreciated, however, that the teachings of the present invention may be applied in the same or similar manner to other types of wireless communications in which data is transmitted using packets and communicated via a selected RF band at the same or different carrier frequencies.

The MAC I/F 111 includes a buffer 213 that temporarily stores a received packet for transfer and further processing by the MAC 109. In typical configurations according to the baseline 802.11 standard, the RX processor 121 includes a symbol detector that generates soft decisions and hard decision logic that selects from among the soft decisions resulting in a final packet stored in the buffer 213. The stored packet included at least one cyclical redundancy code (CRC) provided within corresponding fields of the packet. The TX processor 113, for example, includes CRC logic (not shown) that generates and appends a CRC to each packet prior to submission to the TX chain 115. Received packets are stored in the buffer 213 and then serially shifted out to the MAC 109. According to standard embodiments, the MAC 109 included CRC error detection logic (not shown) that used the appended and transmitted CRC to determine whether the packet was valid. A mismatched CRC resulted in rejection of the packet.

The packet error rate (PER) for wireless configurations, however, is significantly high such that additional error correction techniques are desired to improve performance. The RX processor 121 includes a forward error correction (FEC) system and method according to an embodiment of the present invention that is capable of detecting and correcting up to a predetermined number of symbols in the decoded packet. A symbol detector 203 (FIG. 2) in the RX processor 121 correlates each symbol with each of an entire family of symbols and outputs multiple correlation factors with each possible symbol. The symbols having the highest correlation factors are stored in the buffer 213. As described more fully below, rather than ignore the other symbols having lower correlation factors as was typically done in hard decision logic, the FEC scheme described herein compares the highest two correlation factors for each symbol to determine a corresponding symbol quality (SQ) metric or SQ factor. A predetermined number of symbols, referred to as “M”, having the lowest SQ metrics are identified, and the corresponding second choice symbols are stored.

According to embodiments of the present invention, a different CRC value is calculated using each combination of the M predetermined number of first and second choice symbols. The CRC value is either a CRC remainder for comparison with a predetermined value or a CRC for comparison with the transmitted CRC. For example, if M is two (2), so that two second choice symbols are stored corresponding to the two symbols having the lowest SQ metrics, a first CRC value is calculated assuming that the first choice of both of the lowest quality symbols are valid, a second CRC value is calculated assuming that the first choice of the first symbol and the second choice of the second symbol are valid, a third CRC value is calculated assuming that the second choice of the first symbol and the first choice of the second symbol are valid, and a fourth CRC value is calculated assuming that the second choice of both symbols are valid. All of the calculated CRC values are examined to identify which combination is correct, if any. If none of the calculated CRC values result in a CRC match, then the packet is discarded. If more than one calculated CRC value is correct, the packet may either be discarded or additional processing may be performed.

It is noted that standard IEEE 802.11 packets include packet headers that incorporate a 16-bit header CRC. The packet header is followed by a data portion that includes a MAC header, a data payload and a 32-bit data CRC. The present disclosure primarily focuses on forward error correction (FEC) techniques using the data CRC to verify and perform limited error correction of the packet data portion. The principles (and circuitry) may be equally applied, however, to the header CRC to verify and correct the packet header, if necessary or desired. The present invention provides that the MAC CRC function is redundant and may be removed. However, the MAC CRC function may remain intact even though packet validity will already have been determined within the BB processor 107. Another significant benefit of the present invention is that the transmitter portion of the RF transceiver 101 need not be modified. An FEC system according to embodiments of the present invention may be implemented wholly within the receiver portion to provide all of the benefits and advantages.

FIG. 2 is a more detailed block diagram illustrating a portion of an exemplary configuration of the RX processor 121 interfaced to a portion of the MAC interface 111 including the MAC buffer 213. Analog signals (AS) from the RX chain 119 are provided to an analog to digital converter (ADC) 201, which provides corresponding digital signals (DS) to the symbol detector 203. The symbol detector 203 includes correlation logic (not shown) that correlates each digital group of the DS (received symbol) with a predetermined symbol set in an attempt to identify the most likely symbol transmitted. In the embodiment shown, the number of bits per symbol (and bits per digital group) depends the selected rate of operation as identified by a signal R. For example, each digital group and symbol may each have 1, 2, 4 or 8 bits for depending upon the selected rate, including 1, 2, 5.5 or 11 megabits per second (Mbps) operation. For purposes of discussion, it is assumed that each symbol is 8 bits in length, where it is understood that the principles described herein apply equally to any other symbol size. Also, the appropriate symbol family corresponding to the selected symbol size is employed.

The symbol detector 203 outputs a symbol set SYM1 and a corresponding set of correlation factors CFᵢ, where “i” is an index value from 1 to N and where “N” represents the number of symbols of the selected symbol family. For 8 bits, for example, N may be 256, although the symbols may be represented in alternative formats, such as 64 different codes and 4 different phases. In this manner, the symbol detector 203 correlates each possible symbol SYMᵢ with a received digital group and outputs a corresponding correlation factor CFᵢ, which is generally indicative of the probability that the corresponding symbol of the symbol family is the correct symbol. Thus, the larger the correlation factor CFᵢ, the more likely it is that the corresponding symbol SYM, is the correct symbol. The set of symbols SYMᵢ and corresponding correlation factors CFᵢ are provided to symbol select logic 205, which selects first and second symbols SYM1/2 (SYM1 and SYM 2) having the highest correlation factors CF1 and CF2 (CF1/2). In particular, SYM1 has the highest correlation factor CF1 and SYM2 has the second highest correlation factor CF2 of all of the correlation factors CFᵢ. SYM1 is provided to the MAC buffer 213, SYM2 is provided to a rank value filter (RVF) 209, both symbols SYM1/2 are provided to CRC logic 211, and both correlation factors CF1/2 are provided to symbol quality logic 207.

In one embodiment in accordance with IEEE 802.11, the symbols appended at the end of the packet that correspond to the transmitted CRC, or CRCₜ, are simply forwarded and used together with all of the other symbols during determination of calculated CRC values, shown as CRCₖ, which in this case are CRC remainder values. This embodiment is appropriate when the CRC calculation is intended to incorporate CRCₜ for comparison with a predetermined non zero remainder value, such as, for example 0xC704DD7B. It is contemplated that the predetermined remainder value may be any zero or non-zero value, although a non-zero value is preferred. Alternatively, the symbols that correspond to the transmitted CRCₜ are stripped from the packet by the symbol select logic 205 (or other appropriate logic) and provided to CRC control and output logic 215 for purposes of comparison with calculated CRC values, where the calculated CRCₖ values are actual CRC values for comparison with the transmitted value. This configuration is appropriate for embodiments in which the CRC calculation is performed separately from the transmitted CRCₜ. That is, in the first embodiment the calculation of the received CRC value includes the transmitted CRC and in the latter embodiment it does not.

The symbol quality logic 207 compares the two correlation factors CF1/2 and outputs a signal quality (SQ) metric to the RVF 209. In this manner, a separate SQ metric is provided for each symbol. In one embodiment, each SQ metric is calculated as, or is otherwise derived from, the difference between the corresponding correlation factors CF1/2, or SQ=CF1−CF2, so that the higher the SQ metric, the more likely that SYM1 is the correct symbol. The RVF 209 compares each SQ metric as it arrives and determines the M predetermined number of SQ metrics having the lowest value. The lowest SQ metrics and the corresponding SYM2 values are stored. For example, if the M is four (4), then the four SYM2 symbols having the lowest SQ metrics are stored by the RVF 209. It is appreciated that the smaller the SQ value for a symbol SYM1, the more likely it is that the second best symbol, SYM2, is actually the correct value.

The M predetermined number of second choice symbols SYM2 that are stored represent the maximum number of symbols that are correctable for a given packet for purposes of the present invention. The higher the value of M, the greater the number of correctible symbols and thus, theoretically, the greater the performance of the RF transceiver 101. It is noted, however, that the memory and processing resources each grow geometrically with increased M values. Additionally, the undetected error rate increases as M increases in the classical FEC trade-off of detection versus correction. As described below, for example, for a given value of M, 2^{M} different CRC values are calculated or updated for each new symbol. Thus, 16 CRC values are updated and stored for each symbol for M=4, whereas 64 CRC values are updated and stored for M=6. Therefore, a tradeoff between performance and hardware/software resources is determined to select an optimal value of M for a given system.

In one embodiment, the RVF 209 ranks the currently stored SQ metrics from highest to lowest quality. The first four SYM2 symbols and corresponding SQ metrics are initially stored and ranked. Thereafter, the RVF 209 compares the SQ metric of the next received symbol with the best SQ metric of the currently stored SQ metrics (in other words, the “best of the worst” of the currently stored SQ metrics). If the new SQ metric is equal to or better than the best SQ metric of the currently stored SQ metrics, then the new SQ metric and its corresponding SYM2 symbol are ignored. If, however, the new SQ metric is smaller than the best of the worst SQ metrics, then the new SQ metric and its corresponding SYM2 symbol are stored in the RVF 209 to replace the old best of the worst SQ metrics. Furthermore, the RVF 209 re-ranks the stored SQ metrics so that a new best of the worst SQ metric is determined from the updated set of stored SQ metrics. In this manner, after all received symbols of a packet have been processed, the RVF 209 stores M SYM2 values that have the worst SQ metrics for that packet.

As an example, if M is four, then the first four SYM2 and corresponding SQ metrics are initially stored (e.g., SYM2₀₋₃, SQ₀₋₃) and ranked. If the second symbol SYM₁ has the highest SQ metric (SQ₁) of the first four symbols SYM₀₋₃, then the SQ metric (SQ₄) of the fifth symbol, SYM₄, is compared with SQ₁. If SQ₄ is equal to or greater than SQ₁, then the fifth symbol is ignored by the RVF 209. If, however, SQ₄ is less than SQ₁, then the stored SYM2₁ and SQ₁ values are replaced by the SYM2₄ and SQ₄ values, respectively, for a new stored set of values SYM2_{0,2,3,4}, SQ_{0,2,3,4}. Also, the SQ₄ is compared with each of the next highest of the SQ_{0,2,3} values to rank the symbols and to identify which of the new set has the highest SQ metric for purposes of comparison with the next symbol. Operation proceeds in this manner until all symbols have been processed.

The RVF 209 asserts a replace symbol flag (RSF) signal and corresponding replace symbol number (RSN) signal. The RVF 209 asserts the RSF signal when a new SYM2 value and corresponding SQ metric are selected to be stored. The RSN signal identifies which of the old set of SYM2 and SQ metric values is being replaced. In one embodiment, the RSN signal is always updated to point to or otherwise represent the highest SQ metric currently stored since it will always be the replaced value. The CRC logic 211 receives each SYM1/2 set from the symbol select logic 205 and the RSF, RSN signals from the RVF 209. The CRC logic 211 calculates and updates a set of CRC values for each new symbol received. If the RSF signal is not asserted for a new SYM1/2 set, then the SYM1 value is assumed to be valid and used to update all of the CRC values. If, however, the RSF signal is asserted for a new SYM1/2 set, then both SYM1 and SYM2 values are used to update the CRC values. As described more fully below, when the RSF signal is asserted, one-half of the current CRC values associated with a SYM2 symbol indicated by the RSN signal are deemed invalid and replaced by the other half (which correspond to the SYM1 symbol indicated by the RSN signal). The first half of CRCₖ values is updated using the new SYM1 value and the second half is updated using the first half of the CRCₖ values and the new SYM2 value.

The control and output logic 215 asserts an optional header/data (H/D) signal to the CRC logic 211 indicating whether a header or a data CRC is being processed (for embodiments in which both header and data CRCs are evaluated). The header and data CRC calculations are substantially identical except that a different number of CRC bits may be employed (e.g., 16 bits for the header CRC and 32 bits for the data CRC). The control and output logic 215 also asserts the R signal identifying the raw transmission rate of the transceiver 101 indicative of the number of bits per symbol. The control and output logic 215 receives a SIZE signal indicative of the size of the packet for purposes of determining when all of the data has been received. The packet size is transmitted with the packet in the packet header. After all of the symbols of a packet have been received, the control and output logic 215 asserts one or more output data control (ODC) signals to the various processing blocks for reading or otherwise processing results. The set of CRC values calculated by the CRC logic 211, shown as CRCₖ, are each compared by control and output logic 215 to the predetermined value or to the transmitted CRCₜ value for purposes of identifying the appropriate combination of SYM1/2 symbols. The subscript “k” is an index value that varies from 1 to P, where P=2^{M}. The selected SYM2 symbols and corresponding symbol numbers are provided from the RVF 209 to the control and output logic 215 to replace corresponding SYM1 symbols while shifting data out to the MAC 109. In particular, the SYM1 symbols in the MAC buffer 213 are serially shifted out to the control and output logic 215, which correspondingly shifts serial data out to the MAC 109. The control and output logic 215 replaces any of the SYM1 symbols from the MAC buffer 213 with corresponding SYM2 symbols, if necessary, according to the valid combination of SYM1 and SYM2 symbols identified by the correct CRCₖ value.

If none of the CRCₖ values match or if multiple matches occur, an optional error signal ERR is asserted indicating that the packet is not valid. In one embodiment, the ERR signal is provided to the MAC 109. Alternatively, or in addition, the MAC 109 includes separate CRC check logic (not shown) that invalidates the packet. It is noted that if the CRC value calculated using all of the SYM1 values matches the predetermined value or the transmitted CRCₜ, then the packet may be considered valid even if any one or more of the other CRCₖ values match. If the CRC value calculated using all of the SYM1 values does not match but two or more of the other CRCₖ values match, and if additional processing is not to be performed in an attempt to identify the appropriate combination of SYM1/2 values (in which case the SYM1 symbols alone are incorrect), then the control and output logic 215 either asserts the ERR signal or shifts out the SYM1 symbols with the transmitted CRCₜ, in which case the MAC 109 invalidates the packet based on CRC mismatch.

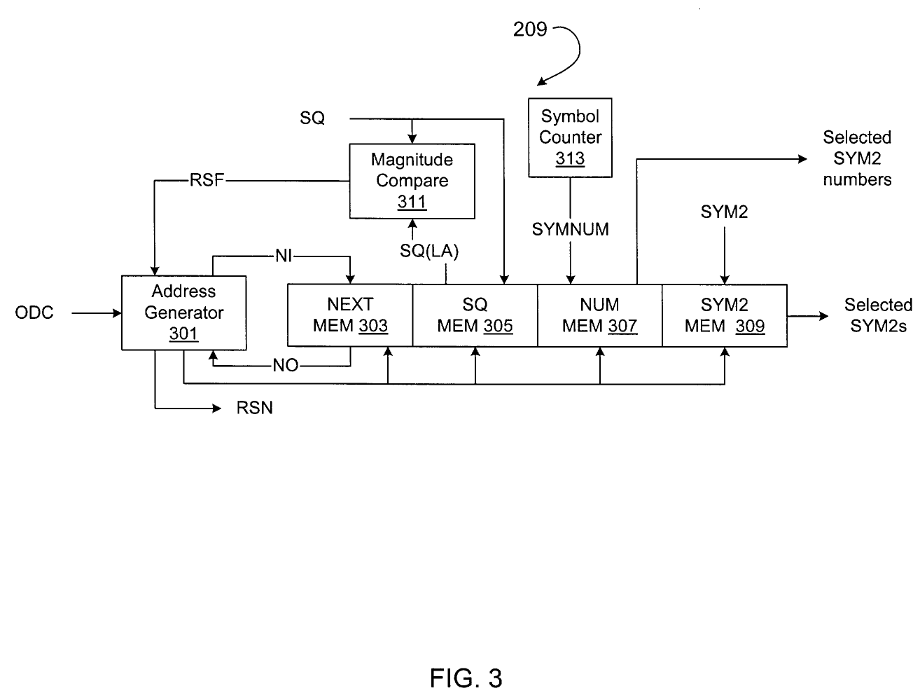

FIG. 3 is a more detailed block diagram of an exemplary embodiment of the RVF 209. Primary control is facilitated by an address generator 301, which controls addressing of a series of memories, including a NEXT memory 303, an SQ memory 305, a NUM memory 307 and a SYM2 memory 309. Each of the memories 303-309 may be implemented using any type of memory devices, such as dynamic random access memory (DRAM) devices, registers, etc. Each of the memories 303-309 has the same number of addressable entries and each address locates corresponding values across the memories 303-309. For example, a given address “a” locates a stored SYM2 symbol in the SYM2 memory 309, a corresponding symbol quality SQ value located at address “a” in the SQ memory 305, and a corresponding symbol number located at address “a” in the NUM memory 307. A symbol counter 313 outputs a symbol number (SYMNUM) to the NUM memory 313, where the symbol counter 313 may be a simple counter that increments for each new or “next” symbol of an incoming packet. The symbol number identifies the corresponding location or relative position of the symbol within a given packet and is used for the purpose of locating and replacing a SYM1 symbol with a SYM2 symbol if necessary.

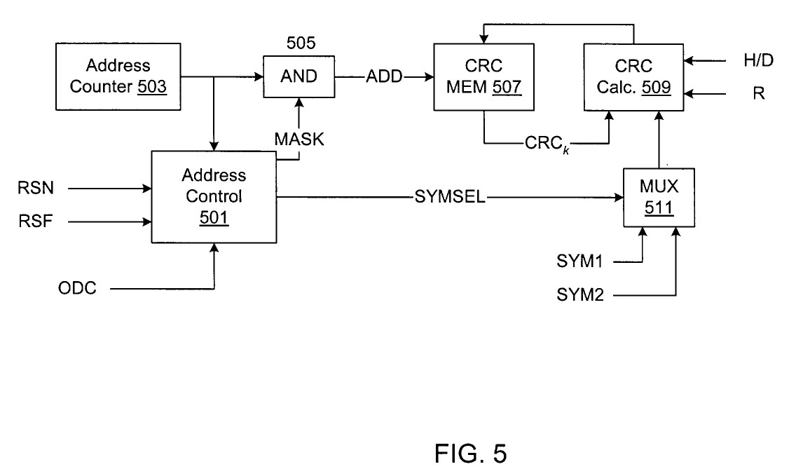

The width of each memory 303-309 depends on the size of the values stored. In one embodiment, each SQ metric and SYM2 symbol is 8 bits in length. If each packet holds up to 65 kilobytes, then the NUM memory 307 and each symbol number is 15 or 16 bits in length. The NEXT memory 303 is provided to store address or pointer values that implement a linked list for the remaining memories 305-309. In one embodiment, for example, the SQ, number and symbol values are randomly stored and the NEXT pointers are used by the address generator 301 to organize the values from largest SQ to smallest SQ. In one embodiment, for example, a largest SQ address (LA) is the address associated with the current largest SQ value in the SQ memory 305. The corresponding location of the NEXT memory 303, or NEXT(LA), stores the address of the second largest SQ value currently stored in the SQ memory 305, e.g., address “SL”. Then the address value stored at NEXT(SL) is the address of the third largest SQ value, and so on. The address in the location of the NEXT memory 303 associated with the smallest SQ value is LA, which points back to the largest SQ value. The size of the NEXT memory 303 depends upon the total number of addressable locations of all of the memories 303-309. For M=4, a minimal embodiment of only four addressable locations is contemplated in which only 2 address bits are necessary. Even if M=4, a larger number of memory locations may be defined to correspond to the size of the CRC memory 507 (FIG. 5) to facilitate logic routines at the expense of a larger memory size. Four address bits are provided to address 16 memory locations, and so on.

The RVF 209 includes a magnitude compare block 311 that compares each new SQ value of the next symbol of the packet with the largest SQ metric currently stored in the SQ memory 305. The address generator 301 provides address LA to the SQ memory 305, which outputs the corresponding largest SQ metric, or SQ(LA), located at address LA to the magnitude compare block 311. If the new SQ metric is greater than or equal to SQ(LA), then the new SYM2 symbol is ignored and the next symbol is examined. If the new SQ is less than SQ(LA), then the magnitude compare block 311 asserts the RSF signal, which is provided to the address generator 301. The address generator 301 stores the new SQ metric in the SQ memory 305 to replace SQ(LA), stores the corresponding symbol number from the symbol counter 313 in the NUM memory 307 to replace NUM(LA), and stores the new SYM2 symbol into the SYM2 memory 309 to replace SYM2(LA). The address generator 301 updates the pointers in the NEXT memory 303 by reading pointers via signal lines NO and writing pointers via signal lines NI. After all of the symbols of the packet have been processed, the RVF 209 provides the selected symbol numbers from the NUM memory 307 and the corresponding selected SYM2 symbols from the SYM2 memory 309 to the control and output logic 215. The term “selected” means those SYM2 symbols that have been filtered by the RVF 209 associated with the lowest M SQ metrics.

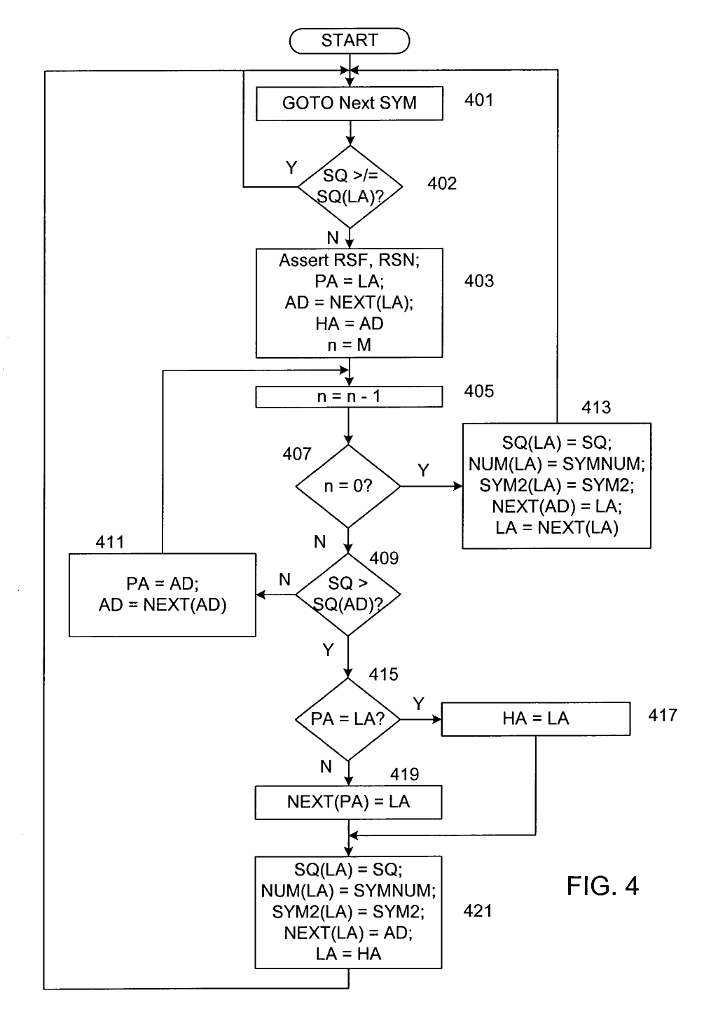

FIG. 4 is a flowchart diagram illustrating operation of the RVF 209 in accordance with an exemplary simplified procedure for determining and storing the SYM2 symbols having the lowest SQ metrics. In this configuration, each of the memories 303-309 include M address locations. The SQ memory 305 may be initialized by storing M superficially high SQ metrics in descending order in which the largest superficial SQ metric is stored at a selected LA. The superficial SQ metrics are different from each other and range from a largest to a smallest, where each is larger than the largest possible SQ metric that may be generated by the symbol quality logic 207. The NEXT memory 303 is initialized to form a linked list between the superficial SQ values from highest to lowest. The illustrated procedure is repeated for each packet.

At a first block 401, operation begins with the next symbol “SYM” of the packet, which is the first symbol in the first iteration (e.g., the first symbol of the data portion). When the next symbol is received, operation proceeds to decision block 402 at which it is queried whether the SQ metric “SQ” of the next symbol SYM is greater than or equal to the current largest SQ value SQ(LA) stored at address LA. If so, operation proceeds back to block 401 to examine the next symbol since the new SYM2 symbol is rejected. Operation loops between blocks 401 and 402 until a new SQ metric is less than SQ(LA). If so, operation proceeds to next block 403 in which the RSF and RSN signals are asserted to alert the CRC logic 211 to update the CRCₖ values using the new SYM2 symbol. Also, a previous_address (PA) value is set equal to LA, an address (AD) value is set equal to the address at NEXT(LA) pointing to the address of the next largest SQ metric, a hold_address (HA) value is set equal to AD for purposes of adjusting LA, if necessary, and an index control value “n” is initially set equal to M for purposes of limiting a number of iterations of the following loop.

At next block 405, n is decremented and then compared to zero in the next decision block 407. Initially assuming that n has not yet reached zero, operation proceeds to next decision block 409 at which it is queried whether the new SQ metric is greater than the SQ metric stored at address AD, or SQ(AD). In the first iteration, since the new SQ metric is smaller than the current largest SQ metric, then the new SQ metric is compared with the currently stored second largest SQ metric SQ(AD). If SQ is not greater than SQ(LA), then the new SQ metric is smaller than the largest two SQ metrics currently stored in the SQ memory 305 and operation proceeds to block 411. At block 411, the PA address is set equal to the address AD and the address AD is then set equal to address currently stored at location NEXT(AD) of the NEXT memory 303. Operation then loops back to block 405 to decrement n and continue the loop. In this manner, operation loops between blocks 405 and 411 until the new SQ metric is deemed larger than a currently stored SQ metric as determined at block 409, or until the new SQ metric has been compared with all stored SQ metrics as determined at block 407.

If n is decremented to zero as determined at block 407, then the new SQ metric is smaller than all of the currently stored SQ metrics and operation proceeds to block 413 to update the memories 303-309 to store the new SYM2 symbol and associated values. In particular, the new SQ metric replaces the old largest SQ metric at SQ(LA) in the SQ memory 305, the current SYMNUM number from the symbol counter 313 is stored at NUM(LA) in the NUM memory 307, and the new SYM2 symbol is stored at location SYM2(LA) in the SYM2 memory 309. In this case, the address AD points to the old smallest SQ metric and LA now points to the new smallest SQ metric, so NEXT(AD) is set equal to LA. LA is then set equal to the address at NEXT(LA) associated with the old second largest SQ metric, which has now become the largest SQ metric. Operation then proceeds back to block 401 to process the next symbol of the packet, if any.

If the new SQ metric is larger than at least one of the currently stored SQ metrics pointed to by address AD as determined at block 409, then operation proceeds to next decision block 415 at which it is determined whether the addresses PA and LA are equal. If so, operation proceeds to block 417 at which the hold address HA is set equal to LA. In this case, the new SQ metric, though smaller than the previous largest stored SQ metric, will become the new largest SQ metric so that LA should not be changed. Note that the hold address HA had previously been set to the address AD at block 403, which is no longer valid in this case. If PA is not equal to LA at block 415, operation proceeds instead to block 419 at which address at NEXT(PA) is set equal to LA. In this case, the new SQ metric is inserted at the appropriate location within the linked list. Operation proceeds to block 421 from either blocks 417 or 419, where the new SQ metric replaces the old largest SQ metric at SQ(LA) in the SQ memory 305, the new SYMNUM number from the symbol counter 313 is stored at NUM(LA) in the NUM memory 307, and the new SYM2 symbol is stored at location SYM2(LA) in the SYM2 memory 309. Also, the address within the NEXT memory 303 at NEXT(LA) is updated with the address AD, and LA is updated with the hold address HA. Operation then loops back to block 401 to process the next symbol in the packet, if any. The RSN signal reflects the LA address since it is always the value to be replaced.

FIG. 5 is a more detailed block diagram of an exemplary configuration of the CRC logic 211. The primary control is provided by address control logic 501 which receives the RSN and RSF signals. The address control logic 501 asserts a symbol select (SYMSEL) signal to a multiplexor (MUX) 511, which selects between the SYM1 and SYM2 symbols. A CRC calculator 509 updates each CRCₖ value stored in the CRC memory 507 using a selected one of SYM1 and SYM2 symbols from the MUX 511 and stores the updated CRCₖ value back into the CRC memory 507. The CRC calculator 509 receives the H/D and R signals to identify the appropriate CRC to calculate (header vs. data) and the number of bits per symbol (determined by the selected rate). It is noted that all of the CRCₖ values are updated with each new packet symbol of the packet. In the exemplary embodiment in which M=4 and in which there are 16 CRCₖ values, the CRC logic 211 operates approximately 16 times faster than the RVF 209. An address counter 503 increments with each clock cycle to step through each of the memory locations of the CRC memory 507. The output of the address counter 503 is provided to the address control logic 501 and to AND logic 505. The AND logic 505 asserts a modified address value ADD to the CRC memory 507 to address the desired CRCₖ value as output from the CRC memory 507 to the CRC calculator 509. The address control logic 501 outputs a MASK signal to another input of the AND logic 505. In this manner, the simple address provided from the address counter 503 is modified by the AND logic 505 as controlled by the MASK signal to generate the ADD signal. As further described below, an appropriate address bit of the output of the address counter 503 is masked by the AND logic 505 to control which of the stored CRCₖ values is accessed, as further described below.

In operation, while the RSF signal is not asserted, the address control logic 501 asserts the SYMSEL signal to control the MUX 511 to select SYM1 as the update value. In this manner, each of the CRCₖ values is updated using SYM1 since the SYM2 value is discarded or otherwise ignored. When the RSF signal is asserted, the address control logic 501 reads the RSN signal to identify which of the CRCₖ values are no longer valid since they are associated with an “old” SYM2 symbol that is being replaced by the new SYM2 symbol. It is noted that although the old SYM2 symbol is being replaced, half of the CRCₖ values in the CRC memory 507 are still valid since calculated using a potentially valid SYM1 symbol. The new SYM1 symbol may be used to update the “good” half of the CRCₖ values and stored back in the same locations. Furthermore, the “good” half may be used in combination with the new SYM2 symbol to replace the other half of the CRCₖ values in the CRC memory 507. The address control logic 501 controls the MASK signal to force the appropriate bit of the ADD signal to ensure that corresponding values from the good half are output as the CRCₖ values from the CRC memory 507, whereas the CRC calculator 509 updates all of the CRCₖ values using the new SYM1 and SYM2 symbols. In the embodiment shown, the RSF signal is asserted before the RSN signal is updated to reflect the new best of the worst SYM symbol associated with the largest SQ metric currently stored. Thus, the address control logic 501 should latch the RSN signal when the RSF signal is asserted prior to update, or at any other appropriate time determined by logic to identify the appropriate location to be replaced.

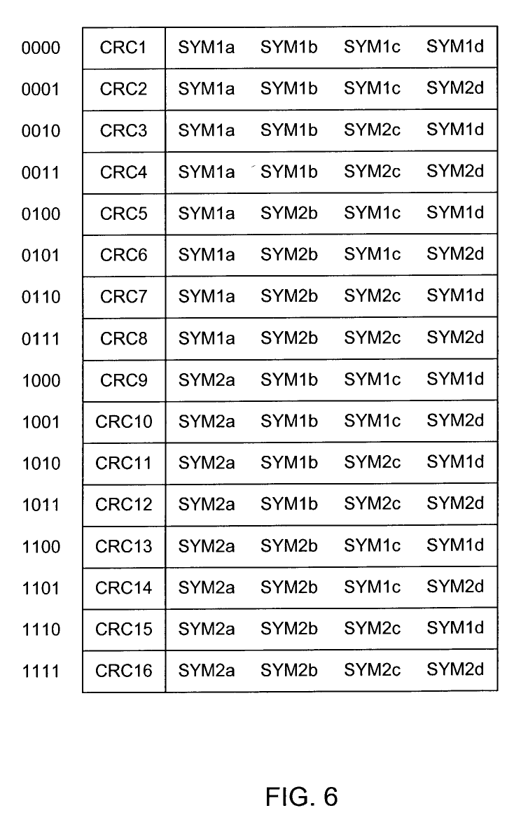

FIGS. 6, 7 and 8 are tabular diagrams illustrating replacement of SYM values to update the CRCₖ values as controlled by the address control logic 501. In this case, M=4 so that there are 16 CRCₖ values to be updated. Four bit binary addresses are listed at the far left in a column 601 for each of the 16 memory locations, listed in increasing binary format as 0000, 0001, 0010, . . . , 1111. The corresponding memory locations store 16 CRCₖ values, shown as CRC1, CRC2, CRC3, . . . , CRC16, respectively, as shown at column 603.

As shown in FIG. 6, the SYM1 and SYM2 values of each of symbols SYMa, SYMb, SYMc and SYMd have been used so far by the CRC calculator 509 to generate the CRC1-CRC16 values shown. The CRC1 value stored at address 0000 was generated using the SYM1 symbol for each of symbols SYMa, SYMB, SYMc and SYMd, or SYM1a, SYM1b, SYM1c and SYM1d (which assumes that all of the SYM1 values are correct and none of the SYM2 values are used). The CRC2 value stored at address 0001 was generated using the SYM1 symbol for each of symbols SYMa, SYMb, and SYMC, while the SYM2 symbol was used for the symbol SYMd, or SYM1a, SYM1b, SYM1c and SYM2d (which assumes that all of the SYM1 values are correct except for SYM1d, which is replaced by SYM2d). Likewise, the CRC3 value stored at address 0010 was generated using the SYM1 symbol for each of symbols SYMa, SYMb, and SYMd, while the SYM2 symbol was used for the symbol SYMC, or SYM1a, SYM1b, SYM2c and SYM1d (which assumes that all of the SYM1 values are correct except for SYM1c, which is replaced by SYM2c). The binary combinations are repeated in this manner up to the last entry, in which the CRC 16 value stored at address 1111 was generated using the SYM2 symbol for each of symbols SYMa, SYMb, SYMc and SYMd, or SYM2a, SYM2b, SYM2c and SYM2d (which assumes that all of the SYM2 values are correct for symbols SYMa, SYMb, SYMc and SYMd).

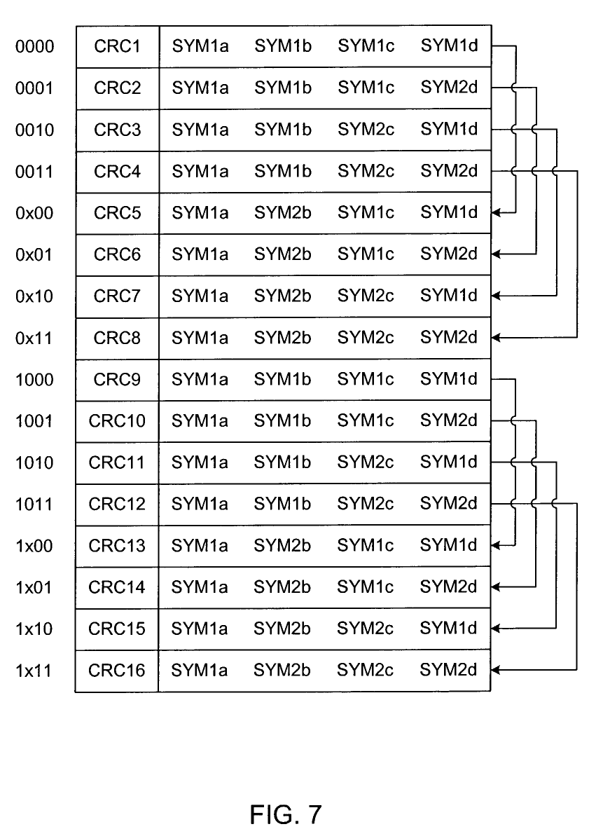

FIG. 7 illustrates modified addressing employed by the address control logic 501 and AND logic 505 while masking the second address bit to replace SYMb with a new symbol SYMe. In this case, the masked bit is shown by an “x” so that the second ADD bit is always a binary zero (0) for the output values, whereas normal addressing is employed for the inputs of the CRC memory 507. In this manner, the CRC1-CRC4 values from address locations 0000-0011, respectively, are output to the CRC calculator 509 as normal during the first four calculations. The CRC1-CRC4 values from address locations 0000-0011, respectively, are output again rather than the CRC5-CRC8 values from address locations 0100-0111, respectively, during the next four calculations since the second most significant address bit is masked to zero. In a similar manner, the CRC9-CRC12 values from address locations 1000-1011, respectively, are output to the CRC calculator 509 as normal during the next four calculations, and the CRC9-CRC12 values from address locations 1000-1011, respectively, are output again rather than the CRC 13-CRC 16 values from address locations 1100-1111, respectively, during the next four calculations. In this manner, the existing CRCₖ values generated using the SYM2b symbol are thrown out in favor of the CRCₖ values generated using the SYM1b symbol during the replacement process.

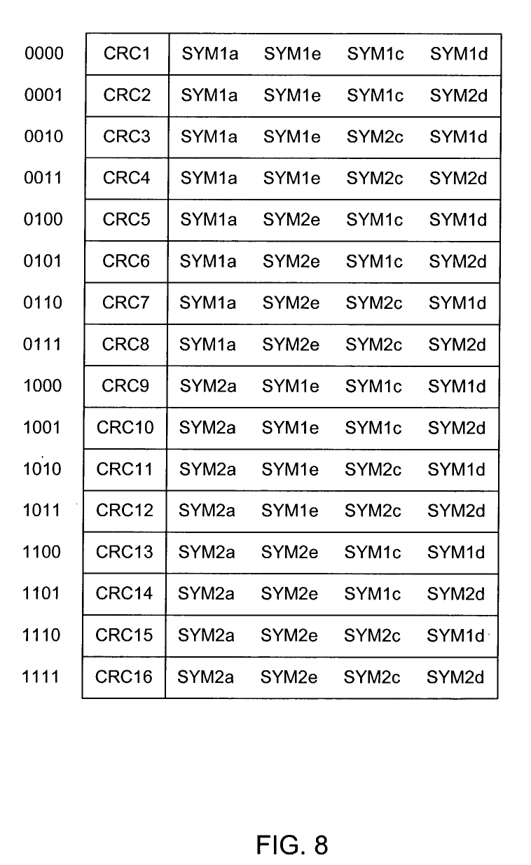

FIG. 8 illustrates the final result after SYMb is replaced with SYMe. In this case, all of the SYM1b and SYM2b values are replaced with the SYM1e and SYM2e values, respectively. It is appreciated that although the SYMb symbols have been replaced by the SYMe symbols for the combinatorial calculations as illustrated, that the SYM1b values were still used to calculate the CRCₖ values. Entry into the tables of FIGS. 6-8 simply show the 2^{M} combinations of the particular M SYM1/2 symbols that have been used for the CRC calculations.

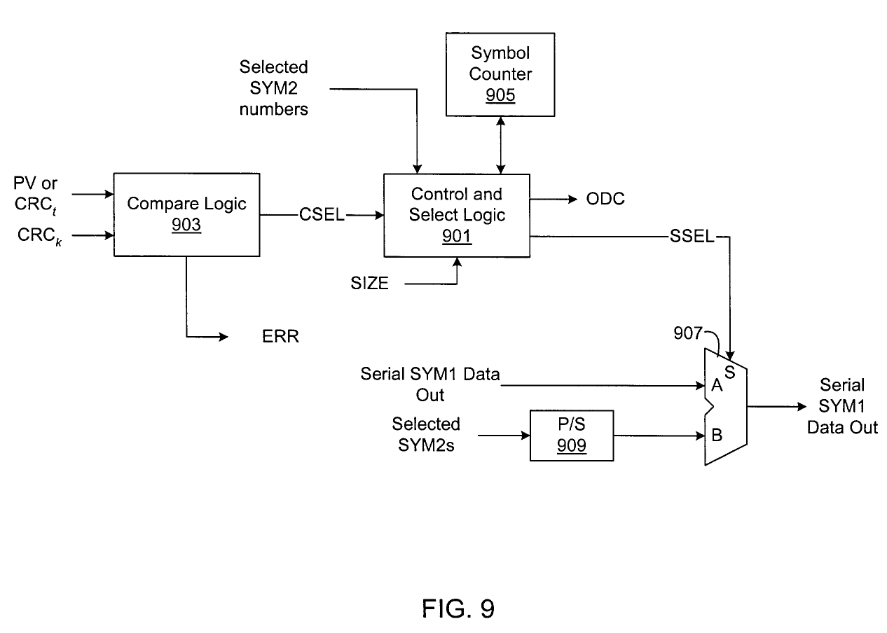

FIG. 9 is a more detailed block diagram of the control and output logic 215. The control and output logic 215 includes control and select logic 901 that asserts the ODC signals after all of the symbols of a packet have been received to initiate data output. The control and output logic 215 employs a symbol counter 905 and the SIZE signal to track symbol progress of the packet. The CRC logic 211 outputs the CRCₖ values to compare logic 903, which determines whether any of the CRCₖ values match the predetermined value (PV) or the transmitted CRCₜ. If a match is not found or if multiple matches occur, the compare logic 903 asserts the ERR signal as previously described. If a match occurs, the compare logic 903 asserts a CRC select (CSEL) signal to the control and select logic 901 that identifies the appropriate combination of SYM1/2 symbols.

To initiate output data, the control and select logic 901 initiates the MAC buffer 213 to begin serially shifting out its stored SYM1 symbols to the control and output logic 215, where the data is provided to a first input (A) of a 2-input MUX 907. The RVF 209 asserts its stored SYM2 symbols from the SYM2 memory 309 when the symbol count matches the symbol number. The outputs of the SYM2 memory 309 are provided to the input of a parallel to serial (P/S) converter 909, which asserts serial data to the second input (B) of the MUX 907. The control and select logic 901 asserts a symbol select (SSEL) signal to the select (S) input of the MUX 907 to select the SYM1 symbols from the MAC buffer 213 or the SYM2 symbols from the P/S converter 909 based on the CSEL signal while data is being serially shifted out of the MUX 907 to the MAC device 109. In this manner, the SYM1/2 combination associated with a correct CRC value, if any, is provided to the MAC device 109 from the output of the MUX 907.

It is noted that the IEEE 802.11 standard timing requirements may be affected by an FEC scheme according to the present invention in that the packet remains within the MAC buffer of the baseband processor until CRC calculations are completed. It is possible, however, to view the BBP and MAC as a single encapsulated functional block, where the arbitrary BBP/MAC interface requirement is modified. Some functions may be moved between the BBP and MAC. For example, the received data CRC calculation is moved from the MAC to the BBP. Also, the data packet de-format, including differential decode, de-ping/pong, and de-scramble) after FEC decode may be moved from the MAC to the BBP FEC decoder. Transmit acknowledge timing may be moved from the MAC to the BBP.

In an FEC system according to embodiments of the present invention, the BB Processor keeps track of the symbols which are likely to have errors using the SQ metric. The BB Processor uses the various combinations of the first and second choice symbols to calculate possible CRC values. The BB Processor uses some of the redundancy in the header and data CRC values to look for a combination which will produce a CRC match.

The BB Processor may be employed to correct erroneous header symbols and de-format the header. The MAC may be implemented to provide the BB Processor processed start of acknowledgement timing information, where the BB Processor transmits the acknowledgement provided by the MAC if the packet is correctable. The MAC may be employed to correct any erroneous data symbols using data provided by the BB Processor. Simulation results using a theoretical diversity scheme with statistically independent antennas has illustrated reduction of the PER by ½ at 50% PER.

Although a system and method according to the present invention has been described in connection with one or more embodiments including a preferred embodiment, it is not intended to be limited to the specific form set forth herein, but on the contrary, it is intended to cover such alternatives, modifications, and equivalents, as can be reasonably included within the spirit and scope of the invention as defined by the appended claims.

1. A forward error correction system for a wireless receiver, comprising:
a symbol detector that correlates each received digital group of a packet with a selected symbol family and that provides a set of possible symbols and corresponding correlation factors for each digital group;
a symbol selector, coupled to the symbol detector, that selects a plurality of possible symbols that have higher correlation factors for each digital group;
CRC logic, coupled to the symbol selector, that calculates a plurality of possible CRC values for the packet using combinations of the plurality of possible symbols; and
output logic, coupled to the CRC logic, that evaluates the plurality of possible CRC values to determine whether there is a correct symbol combination for the packet.

2. The forward error correction system of claim 1, further comprising:
symbol quality logic, coupled to the symbol selector, that determines a symbol quality metric for each digital group based on a difference between a highest correlation factor and a second highest correlation factor.

3. The forward error correction system of claim 2, further comprising:
a rank value filter, coupled to the symbol selector and the symbol quality logic, that selects a predetermined number of second choice symbols based on the symbol quality metrics.

4. The forward error correction system of claim 3, wherein the rank value filter comprises:
a rank value memory that stores the predetermined number of second choice symbol and corresponding symbol quality metrics;
a magnitude comparator, coupled to the rank value memory, that compares a symbol quality metric of each digital group with at least one stored symbol quality metric; and
an address control generator, coupled to the rank value memory and the magnitude comparator, that replaces a stored symbol quality metric and corresponding second choice symbol with a symbol quality metric and corresponding second choice symbol of a next digital group in the rank value memory if the stored symbol quality metric indicates a higher quality symbol than the symbol quality metric of the next digital group.

5. The forward error correction system of claim 4, wherein the address control generator operates to store in the rank value memory the predetermined number of second choice symbols having lower symbol quality metrics of the digital groups of the packet.

6. The forward error correction system of claim 5, wherein the rank value memory further stores a symbol number indicative of symbol location in the packet for each stored second choice symbol.

7. The forward error correction system of claim 6, further comprising:
the rank value memory further storing a next pointer for each stored second choice symbol; and
the address control generator programming each next pointer of each stored second choice symbol to establish a linked list of stored symbol quality metric from highest to lowest.

8. The forward error correction system of claim 5, wherein the CRC logic calculates each of the plurality of possible CRC values using combinations of stored second choice symbols and corresponding first choice symbols.

9. The forward error correction system of claim 8, wherein:
the rank value filter examines each of the digital groups of the packet one at a time in the order received and updates the stored second choice symbols if necessary;
the rank value filter providing an update signal indicating a currently stored second choice symbol to be replaced; and
the CRC logic receiving the update signal and updating the plurality of possible CRC values for the packet.

10. The forward error correction system of claim 9, wherein the CRC logic uses a first half of the plurality of possible CRC values and a subsequent first choice symbol to update the first half and wherein the CRC logic uses the first half of the plurality of possible CRC values and a second symbol corresponding to the subsequent first choice symbol to update a second half of the plurality of possible CRC values.

11. The forward error correction system of claim 10, wherein the CRC logic comprises:
a CRC memory for storing the plurality of possible CRC values;
a CRC calculator that calculates each possible CRC value using a selected first or second choice symbol;
select logic that selects between first and second choice symbols of each digital group based on a symbol select signal; and
address control logic that provides an existing CRC value from the CRC memory to the CRC calculator and that asserts the symbol select signal to select between first and second choice symbols.

12. The forward error correction system of claim 11, wherein the output logic comprises:
a buffer that stores a first choice symbol for each digital group;
compare logic, coupled to the CRC logic, that compares each of the plurality of possible CRC values with a predetermined value in an attempt to determine a correct symbol combination for the packet; and
control and select logic, coupled to the buffer, the compare logic, and the rank value filter, that selects between each stored second choice symbols and corresponding first choice symbols for each corresponding digital group according to the determined correct symbol combination to determine the packet.

13. The forward error correction system of claim 1, wherein the CRC values comprise CRC remainders and wherein the predetermined value is a non-zero value.

14. A wireless transceiver, comprising:
a radio for transmitting and receiving radio frequency (RF) packets and for converting between RF and baseband signals;
an analog to digital converter (ADC) that converts received baseband signals into digital signals;
a baseband processor, comprising:
a symbol detector that correlates each received digital group of the received digital signals with a selected symbol family and that provides a set of possible symbols and corresponding correlation factors for each digital group;
a symbol selector, coupled to the symbol detector, that selects a plurality of possible symbols that have higher correlation factors for each digital group;
CRC logic, coupled to the symbol selector, that calculates a plurality of possible CRC values for the packet using combinations of the plurality of possible symbols;
output logic, coupled to the CRC logic, that evaluates the plurality of possible CRC values to determine whether there is a correct symbol combination for the packet; and
a packet buffer for storing the packet; and
a medium access control (MAC) device coupled to the baseband processor.

15. The wireless transceiver of claim 14, wherein the baseband processor further comprises:
symbol quality logic, coupled to the symbol selector, that determines a symbol quality metric for each digital group based on a difference between a highest correlation factor and a second highest correlation factor;
a rank value filter, coupled to the symbol selector and the symbol quality logic, that selects a predetermined number of second choice symbols having lowest symbol quality metrics;
wherein the CRC logic calculates the plurality of possible CRC values using combinations of the selected predetermined number of second choice symbols and corresponding first choice symbols; and
wherein the output logic compares the possible CRC values with a predetermined value.

16. A method of forward error correction for a wireless receiver, comprising:
correlating digital groups of a packet with a symbol family and providing possible symbols and corresponding correlation factors;
selecting a plurality of the possible symbols for each digital group that have higher correlation factors compared to other possible symbols;
determining a plurality of possible CRC values for the packet using combinations of the plurality of possible symbols for each digital group; and
determining if any of the plurality of possible CRC values indicates a valid packet.

17. The method of claim 16, wherein said selecting a plurality of the possible symbols for each digital group comprises selecting a first choice symbol having a highest correlation factor and a second choice symbol having a second highest correlation factor.

18. The method of claim 17, further comprising determining a symbol quality factor for each digital group based on a difference between the highest and second highest correlation factors.

19. The method of claim 18, further comprising:
selecting a predetermined number of second choice symbols based on symbol quality factors; and
wherein said determining a plurality of possible CRC values comprises calculating each possible CRC value using a different combination of the selected second choice symbols and corresponding first choice symbols.

20. The method of claim 19, wherein said selecting a predetermined number of second choice symbols comprises selecting the second choice symbols associated with lower symbol quality metrics than other symbols.

21. The method of claim 20, further comprising:
storing the predetermined number of second choice symbols and corresponding symbol quality metrics;
for each subsequent digital group of the packet, comparing a symbol quality metric corresponding to the subsequent digital group with a stored symbol quality metric; and
if the symbol quality metric corresponding to the subsequent digital group indicates a lower quality packet, replacing a stored second choice symbol and corresponding symbol quality metric with the second choice symbol and corresponding symbol quality metric corresponding to the subsequent digital group.

22. The method of claim 21, further comprising:
ranking the predetermined number of stored second choice symbols according to symbol quality metric from highest to lowest;
said comparing a symbol quality metric corresponding to the subsequent digital group with a stored symbol quality metric comprising comparing the highest stored symbol quality metric with the symbol quality metric corresponding to the subsequent digital group; and
after said replacing, re-ranking the predetermined number of stored second choice symbols according to symbol quality metric from highest to lowest.

23. The method of claim 22, further comprising:
storing the plurality of possible CRC values based on the predetermined number of stored second choice symbols; and
after said replacing, re-calculating and updating the stored plurality of possible CRC values using the newly stored second choice symbol.

24. The method of claim 23, wherein said calculating and updating comprises:
updating a first half of the stored plurality of possible CRC values using the first half of the stored plurality of possible CRC values and a first choice symbol corresponding with the newly stored second choice symbol; and
updating a second half of the stored plurality of possible CRC values using the first half of the stored plurality of possible CRC values and the newly stored second choice symbol.

25. The method of claim 16, wherein said determining if any of the plurality of possible CRC values indicates a valid packet comprises comparing the plurality of possible CRC values with a predetermined value.

26. The method of claim 25, wherein the CRC values comprise CRC remainders and wherein the predetermined value is a non-zero value.

27. The method of claim 25, wherein the CRC values comprise CRCs and wherein the predetermined value is a CRC transmitted with the packet.
